(19) United States
(12) Patent Application Publication
(10) Pub. No.: US 2026/0287638 A1
(43) Pub. Date: Sep. 24, 2026

(54) ON-DIE PARAMETER MEASURING CIRCUIT AND METHOD FOR OPERATING THE SAME

(71) Applicant: TAIWAN SEMICONDUCTOR MANUFACTURING COMPANY LTD., HSINCHU (TW)

(72) Inventors: YI-HSIANG WANG, NEW TAIPEI CITY (TW); SZU-CHUN TSAO, HSINCHU CITY (TW); SHIH JIE HUANG, TAICHUNG CITY (TW)

(21) Appl. No.: 19/087,624

(22) Filed: Mar. 24, 2025

(51) Int. Cl. G01R 31/26

(52) U.S. Cl. CPC G01R 31/2621

(57) ABSTRACT

The present disclosure provides an integrated circuit which includes a plurality of devices under test, a parameter measuring circuit, and a switch circuit. The switch circuit includes a plurality of respective switch sets of the plurality of devices under test. One of the plurality of devices under test is activated by its respective switch set in response to a control signal from external test equipment. The parameter measuring circuit is configured to generate an output current with an adjustable mirror ratio in response to a test current generated by the activated device under test, and send the output current to the external test equipment for measurement.

### BACKGROUND

The semiconductor integrated circuit (IC) industry has grown rapidly due to advancements in IC materials and design. Each new generation of ICs features smaller and more complex circuits than the previous one. During the fabrication of semiconductor devices, one or more testing processes are involved, often utilizing on-chip structures for testing purposes.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of an IC testing system in accordance with some embodiments.

FIG. 2 is a diagram illustrating connection between the DUTs, switch circuit, and ODP measuring circuit in the IC testing system in FIG. 1.

FIG. 3 is a diagram illustrating a test scenario 300 of two DUTs of different types in accordance with some embodiments of the present disclosure.

FIG. 4 is a diagram illustrating a test scenario 400 of two DUT groups of different types in accordance with some embodiments of the present disclosure.

FIG. 5A is a schematic diagram of the second measuring circuit 132 in the embodiment of FIG. 2.

FIG. 5B is a schematic diagram of the first measuring circuit 131 in the embodiment of FIG. 2.

FIG. 6 is diagram illustrating a three-dimensional integrated circuit package including two dies in accordance with some embodiments of the present disclosure.

FIG. 7 is a flowchart of a method for operating an on-die parameter measuring circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

In some embodiments, on-die parameters of each device under test (DUT) within an integrated circuit can be ascertained by measuring the current of each DUT, which may vary widely due to the diverse types of DUTs. For DUTs with smaller current, a large off-chip load capacitance can prolong the testing duration due to the extended charging time required to reach a target voltage level. Conversely, for DUTs with larger current, a minimal IR (current-resistance) drop may be necessary, potentially necessitating increased metal routing efforts. Additionally, some advanced technology nodes, which comprise solely core devices (e.g., the voltage difference between any two terminals of a core device is less than a specified voltage threshold, such as 0.75V), may encounter voltage difference reliability issues (e.g., the voltage difference between any two terminals of a core device exceeds the specified voltage threshold).

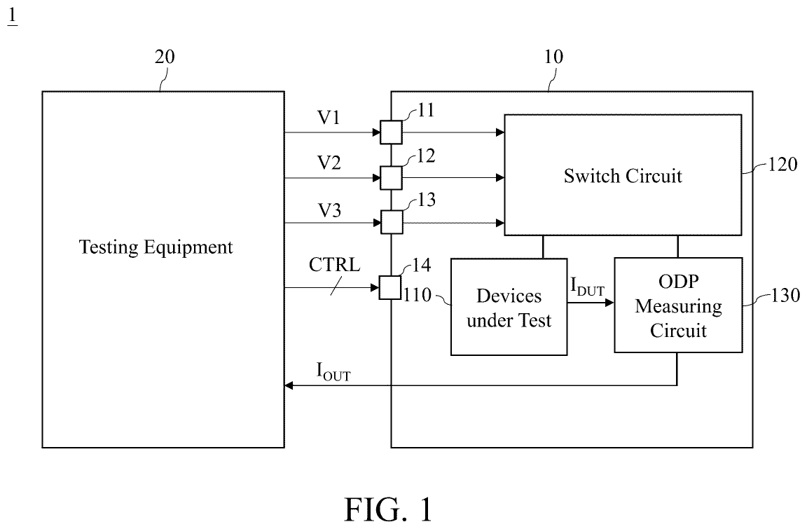

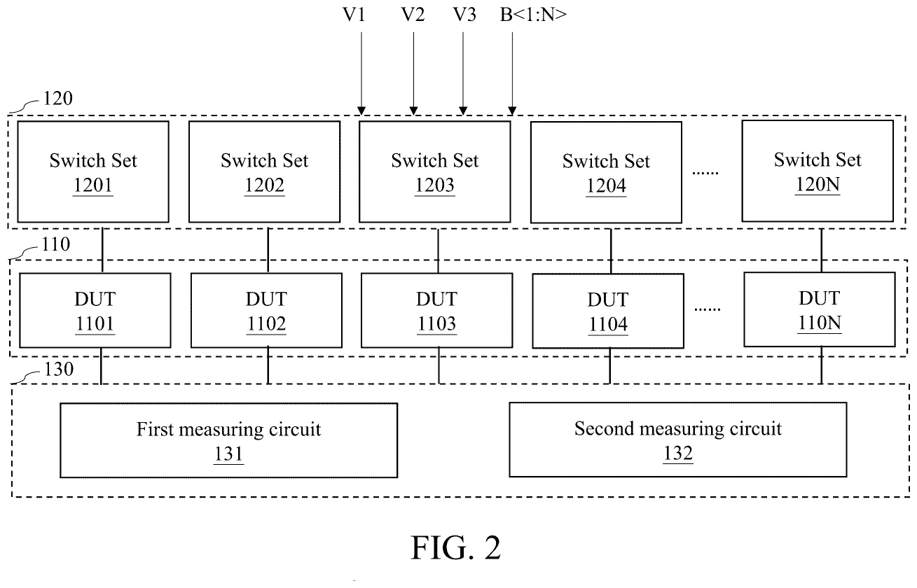

FIG. 1 is a block diagram of an IC testing system in accordance with some embodiments. FIG. 2 is a diagram illustrating connection between the DUTs, switch circuit, and ODP measuring circuit in the IC testing system in FIG. 1.

In some embodiments, the IC testing system 1 may include test equipment 20, and an integrated circuit 10. The test equipment 20 is configured to measuring the on-die parameters (ODP) of devices under test (DUTs) 110 within the integrated circuit 10. The integrated circuit 10 may include a plurality of DUTs 110, a switch circuit 120, and an ODP measuring circuit 130. In some embodiments, the test equipment 20 (or an external voltage supply device) may provide voltage signals V1, V2, and V3 to the integrated circuit 10 through power pads 11, 12, and 13, respectively. The voltage domain of the voltage signals V1, V2, and V3 may be between a high voltage V_{HIGH} and a reference voltage V_{SS}. Additionally, the test equipment 20 may further send a control signal CTRL to the integrated circuit 10 via input/output (I/O) pad 14, enabling the switch circuit 120 to select one of the DUTs for measuring the current the selected DUT.

Referring to FIG. 2, in some embodiments, the DUTs 110 may include DUTs 1101 to 110N, that are circuits in different types designed for testing semiconductor circuits or components fabricated on a semiconductor wafer. For example, a DUT can be in a variety of different devices, such as a MOSFET (metal oxide semiconductor field-effect transistor), a BJT (bipolar junction transistor), a resistor, a metal wire, a via, etc., but the present disclosure is not limited thereto. The switch circuit 120 may include a plurality of switch sets 1201 to 120N that can be selectively activated and deactivated (e.g., turned on and off, or closed and opened). For example, a switch set may include a plurality of switches that correspond to one of the DUTs 110. When a specific DUT among the DUTs 1101 to 110N is selected by the corresponding bit of the control signal B<1:N>, the switches in the switch set corresponding to the specific DUT is activated, thereby providing the voltage signals V1, V2, and V3 to different terminals of the specific DUT.

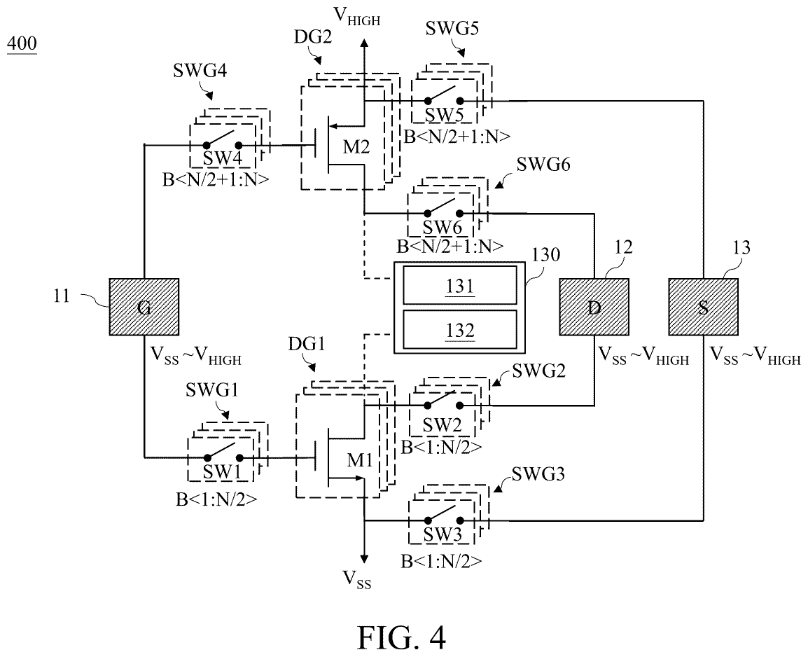

In some embodiments, for purposes of description, the DUTs 110 can be categorized into N-type transistor devices and P-type transistor devices. In addition, a half of the DUTs 110 are N-type transistor devices, while another half of the DUTs are P-type transistor devices. For brevity, the DUTs 110 indexed from 1 to N/2 (e.g., first half, such as DUTs 1101 to 110(N/2)) are N-type transistor devices, and the DUTs 110 index from (N/2+1) to N (e.g., second half, such as DUTs 110(N/2+1) to 110N) are P-type transistor devices. Additionally, each of DUTs 110 in the first half may be selected by a respective bit of the lower half of the control signal B, such as B<1:N/2>, and each of DUTs in the second half may be selected by a respective bit of the upper half of the control signal B, such as B<N/2+1:N>. More details about selecting one of the DUT will be described with reference to FIG. 4.

In some embodiments, the switch circuit 120 is configured to receive the voltage signals V1, V2, and V3, and determine which portion of the DUTs 110 is selected based on the voltage ranges of the voltage signals V1, V2, and V3. For example, the switches within the switch sets for the DUTs being P-type transistor devices are turned off when the voltage range of the voltage signals V1, V2, and V3 are between voltages V_{MID} and V_{SS}, where the middle power supply voltage V_{MID} is between the high power supply voltage V_{HIGH} and the reference voltage V_{SS}. In various non-limiting embodiments, the high power supply voltage V_{HIGH}, the middle power supply voltage V_{MID}, and the reference voltage V_{SS} may be 1.5V, 0.75V, and 0V, respectively.

In some embodiments, the ODP measuring circuit 130 is configured to generate an output current in response to a test current I_{DUT} generated by the selected DUT during the ODP test. Referring to FIG. 2, the ODP measuring circuit 130 includes a first measuring circuit 131 and a second measuring circuit 132. The first measuring circuit 131 is configured to generate an output current I_{OUT} in response to the test current I_{DUT} generated by the selected DUT within the first half of the DUTs 110, whereas the second measuring circuit 132 is configured to generate an output current I_{OUT} in response to the test current I_{DUT} generated by the selected DUT within the second half of the DUTs 110. Specifically, the DUTs 1101 to 110N within the integrated circuit 10 are core devices, and the voltage difference between any two terminals of each DUT 1101 to 110N should be limited to a specified voltage threshold, such as 0.75V. Exceeding this specified voltage threshold between any two terminals of a selected DUT may result in damage to the DUT.

For example, if the source terminal of a selected P-type transistor DUT 110 is connected to the high power supply voltage V_{HIGH}, the drain terminal of the selected P-type transistor DUT 110 should be connected to the middle power supply voltage V_{MID} instead of the reference voltage VSS, thereby preventing damage to the selected P-type transistor DUT 110. Conversely, if the source terminal of a selected N-type transistor DUT 110 is connected to the reference voltage V_{SS}, the drain terminal of the selected N-type transistor DUT 110 should be connected to the middle power supply voltage V_{MID} instead of the high power supply voltage V_{HIGH}, thereby preventing damage to the selected N-type transistor DUT 110.

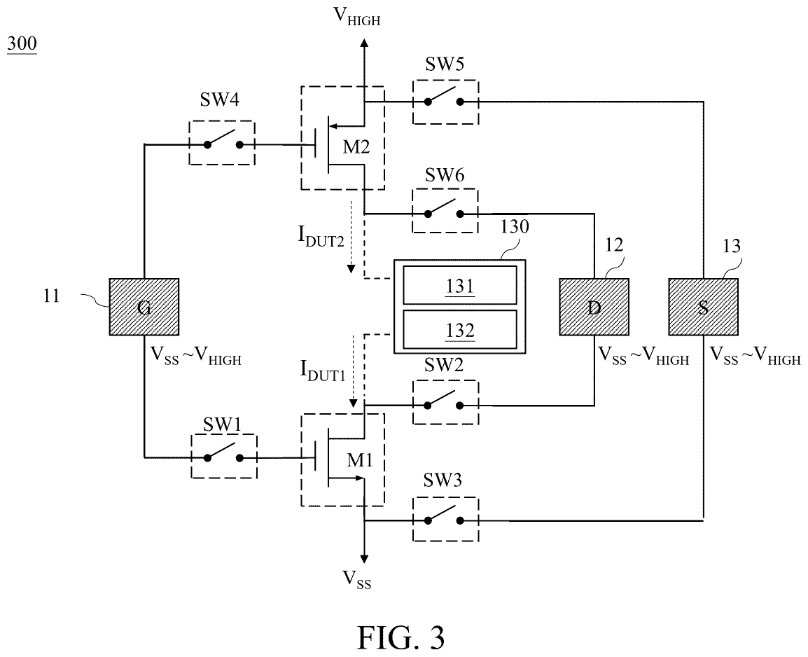

FIG. 3 is a diagram illustrating a test scenario 300 of two DUTs of different types in accordance with some embodiments of the present disclosure.

In some embodiments, the test scenario 300 includes transistors M1 and M2, which are two DUTs among the DUTs 110, where transistor M1 is an N-type transistor, and transistor M2 is a P-type transistor. For example, transistor M1 includes a gate terminal coupled to the power pad 11 through switch SW1, a drain terminal coupled to the power pad 12 through switch SW2, and a source terminal coupled to the power pad 13 through switch SW3. Switches SW1, SW2, and SW3 can be collectively regarded as a first switch set for transistor M1. Additionally, the drain terminal is coupled to the second measuring circuit 132 within the ODP measuring circuit 130. When transistor M1 is selected and activated, the second measuring circuit 132 can receive the test current I_{DUT} from transistor M1 and generate an output current I_{OUT} based on the received test current I_{DUT}. Similarly, transistor M2 includes a gate terminal coupled to the power pad 11 through switch SW4, a drain terminal coupled to the power pad 12 through switch SW5, and a source terminal coupled to the power pad 13 through switch SW6. Switches SW4, SW5, and SW6 can be collectively regarded as a second switch set for transistor M2.

In some approaches, each DUT is equipped with its own power pads to receive input voltage signals at the gate, drain, and source terminals. The voltage range of these input signals should be carefully controlled to avoid damaging the switches of the core devices within each DUT. Consequently, a significant number of DUTs can occupy a substantial portion of the area of an integrated circuit in these approaches. In contrast, transistors M1 and M2 in FIG. 3 utilize shared power pads 11, 12, and 13 during their respective ODP tests. This proposed circuit design can be adapted to accommodate two groups of DUTs of different types. Therefore, the cost associated with additional power pads can be reduced by using common power pads between the two DUT groups.

In some embodiments, switches SW1, SW2, and SW3 in the first switch set may operate in a low voltage range. This indicates that they are turned on (e.g., activated) when their respective supplied voltage signal are within a low voltage range, such as between voltages V_{SS} and V_{MID}, and turned off (e.g., deactivated) when their respective supplied voltage signals are within a high voltage range, such as between voltage V_{MID} and V_{HIGH}. In some embodiments, switches SW4, SW5, and SW6 in the second switch set may operate in a high voltage range. This indicates that they are turned on (e.g., activated) when their respective supplied voltage signal are within a high voltage range, such as between voltages V_{MID} and V_{HIGH}, and turned off (e.g., deactivated) when their respective supplied voltage signals are within a low voltage range, such as between voltage V_{SS} and V_{MID}.

In some embodiments, the first switch set is controlled by a first respective bit in the control signal B[1:N], and the second switch set is controlled by a second respective bit in the control signal B[1:N]. Specifically, one of the first switch set and second switch set is activated at once, indicating that one of transistors M1 and M2 is tested at one time. This can ensure that transistor M1 or M2 can operate within a safe voltage range, thereby preventing damage to transistor M1 or M2 caused by high voltage difference between any two terminals of transistors M1 or M2.

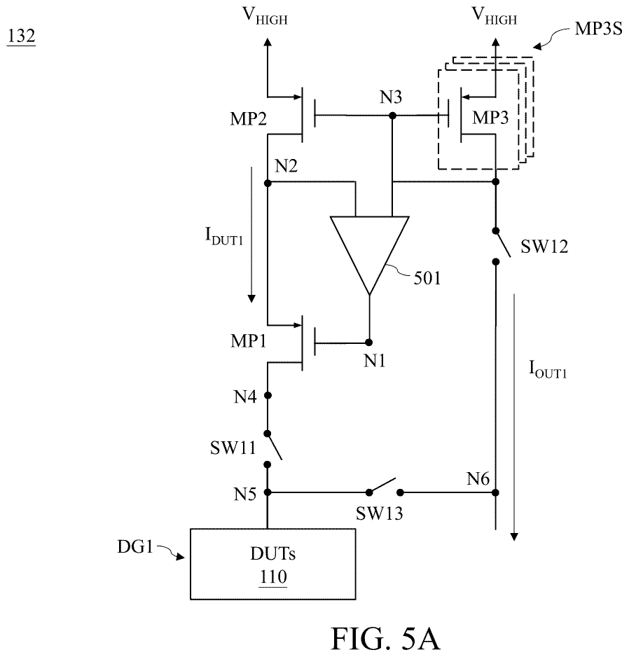

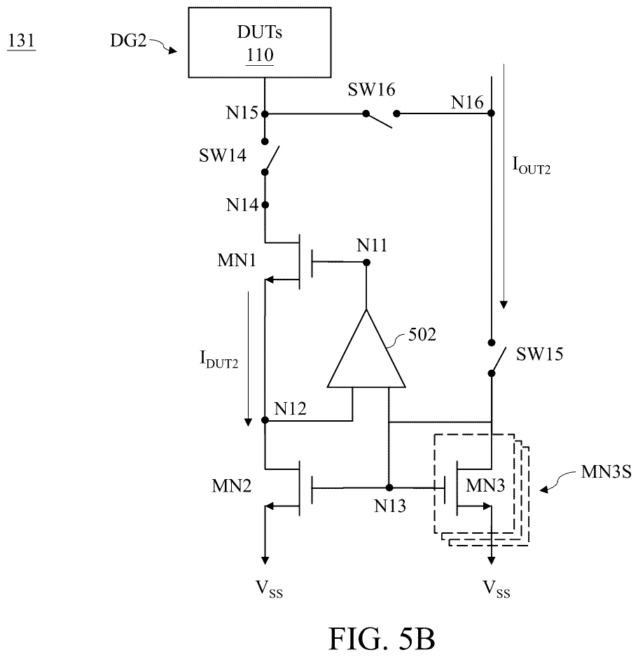

In the first scenario, the voltage signals V1, V2, and V3 provided to the power pads 11, 12, and 13 are within the low voltage range, such as between voltages V_{SS} and V_{MID}, and thus, the first switch set, which includes switches SW1 to SW3, is activated. The voltage level of the voltage signals V1, V2, and V3 can be properly controlled to turn on transistor M1, which may be an N-type transistor. For example, the voltage signals V1 and V2 can be set to the high power supply voltage V_{HIGH}, and the voltage signal V3 can be set to the reference voltage V_{SS}. It should be noted that the second switch set, which includes switches SW4 to SW6, remains deactivated during this period. Accordingly, the second measuring circuit 132 can generate an output current I_{OUT1} in response to the test current I_{DUT1} generated by the activated transistor M1. Further details regarding the second measuring circuit 132 will be provided with reference to FIG. 5A.

In the second scenario, the voltage signals V1, V2, and V3 provided to the power pads 11, 12, and 13 are within the high voltage range, such as between voltages V_{MID} and V_{HIGH}, and thus, the second switch set, which includes switches SW4 to SW6, is activated. The voltage level of the voltage signals V1, V2, and V3 can be properly controlled to turn on transistor M2, which may be a P-type transistor. For example, the voltage signals V1 and V3 can be set to the middle power supply voltage V_{MID}, and the voltage signal V2 can be set to the high power supply voltage V_{HIGH}. It should be noted that the first switch set, which includes switches SW1 to SW3, is deactivated at this time. Accordingly, the first measuring circuit 131 can generate an output current I_{OUT2} in response to the test current I_{DUT2} generated by the activated transistor M2. Further details regarding the first measuring circuit 131 will be provided with reference to FIG. 5B.

FIG. 4 is a diagram illustrating a test scenario 400 of two DUT groups of different types in accordance with some embodiments of the present disclosure.

In some embodiments, the test scenario 400 includes two DUT groups DG1 and DG2, which includes N-type transistors and P-type transistors, respectively. For example, the first DUT group DG1 may correspond to the first half of the DUTs 110, such as DUT 1101 to 110(N/2) shown in FIG. 2 (e.g., N/2 N-type transistors), while the second DUT group DG2 may correspond to the second half of the DUTs 110, such as DUT 110(N/2+1) to DUT 110N shown in FIG. 2 (e.g., N/2 P-type transistors).

Additionally, each DUT in the first DUT group DG1 is equipped with its own switch set, including switches SW1, SW2, and SW3. The respective switches SW1, SW2, and SW3 of each DUT in the first DUT group DG1 may form switch groups SWG1, SWG2, and SWG3, respectively, as depicted in FIG. 4. Similarly, each DUT in the second DUT group DG2 is equipped with its own switch set, including switches SW4, SW5, and SW6. The respective switches SW4, SW5, and SW6 of each DUT in the second DUT group DG2 may form switch groups SWG4, SWG5, and SWG6, respectively, as depicted in FIG. 4.

In some embodiments, each transistor M1 within the first DUT group DG1 includes a gate terminal coupled to the power pad 11 through its respective switch SW1, a drain terminal coupled to the power pad 12 through its respective switch SW2, and a source terminal coupled to the power pad 13 through its respective switch SW3. Respective switches SW1, SW2, and SW3 of each transistor M1 within the first DUT group DG1 can be collectively regarded as a respective first switch set for each transistor M1. Similarly, each transistor M2 within the second DUT group DG2 includes a gate terminal coupled to the power pad 11 through its respective switch SW4, a drain terminal coupled to the power pad 12 through its respective switch SW5, and a source terminal coupled to the power pad 13 through its respective switch SW6. Respective switches SW4, SW5, and SW6 of each transistor M2 within the second DUT group DG2 can be collectively regarded as a respective second switch set for each transistor M2.

In some embodiments, switches SW1, SW2, and SW3 in the respective first switch set may operate in a low voltage range. This indicates that they are turned on (e.g., activated) when their respective supplied voltage signal are within a low voltage range, such as between voltages V_{SS} and V_{MID}, and turned off (e.g., deactivated) when their respective supplied voltage signals are within a high voltage range, such as between voltage V_{MID} and V_{HIGH}. In some embodiments, switches SW4, SW5, and SW6 in the respective second switch set may operate in a high voltage range. This indicates that they are turned on (e.g., activated) when their respective supplied voltage signal are within a high voltage range, such as between voltages V_{MID} and V_{HIGH}, and turned off (e.g., deactivated) when their respective supplied voltage signals are within a low voltage range, such as between voltage V_{SS} and V_{MID}.

In some embodiments, the first switch set of each transistor M1 within the first DUT group DG1 is controlled by a first respective bit in the control signal B[1:N/2], and the second switch set of each transistor M2 within the second DUT group DG2 is controlled by a second respective bit in the control signal B[N/2+1:N]. Specifically, one of the first switch sets and second switch sets is activated at once, indicating that one transistor M1 or M2 within the first DUT group DG1 or the second DUT group DG2 is tested at one time. This can ensure that a selected one of transistors M1 within the first DUT group DG1 or transistors M2 within the second DUT group DG2 can operate within a safe voltage range, thereby preventing damage to the selected transistor M1 or M2 caused by high voltage difference between any two terminals of the selected transistor M1 or M2.

In the first scenario, the voltage signals V1, V2, and V3 provided to the power pads 11, 12, and 13 are within the low voltage range, such as between voltages V_{SS} and V_{MID}. When the respective bit B[1] in the control signal B[1:N/2] is “1”, the first switch set, including respective switches SW1 to SW3, is activated, thereby selecting the first one of transistors M1 within the first DUT group DG1. Additionally, the voltage level of the voltage signals V1, V2, and V3 can be properly controlled to turn on the selected transistor M1, which may be an N-type transistor. For example, the voltage signals V1 and V2 can be set to the high power supply voltage V_{HIGH}, and the voltage signal V3 can be set to the reference voltage V_{SS}. It should be noted that all switch groups SWG4, SWG5, and SWG6 corresponding to the second switch sets, each includes switches SW4 to SW6, are deactivated at this time. Accordingly, the second measuring circuit 132 can generate an output current I_{OUT1} in response to the test current I_{DUT1} generated by the activated transistor M1 within the first DUT group DG1.

In the second scenario, the voltage signals V1, V2, and V3 provided to the power pads 11, 12, and 13 are within the high voltage range, such as between voltages V_{MID} and V_{HIGH}. When the respective bit B[N/2+1] in the control signal B[N/2+1:N] is “1”, the second switch set, including respective switches SW1 to SW3, corresponding to the first one of transistors M2 within the second DUT group DG2 is activated, thereby selecting the first one of transistors M2 within the second DUT group DG2. Additionally, the voltage level of the voltage signals V1, V2, and V3 can be properly controlled to turn on the selected transistor M2, which may be a P-type transistor. For example, the voltage signals V1 and V3 can be set to the middle power supply voltage V_{MID}, and the voltage signal V2 can be set to the high power supply voltage V_{HIGH}. It should be noted that all switch groups SWG1, SWG2, and SWG3 corresponding to the first switch sets, each includes switches SW1 to SW3, are deactivated at this time. Accordingly, the first measuring circuit 131 can generate an output current I_{OUT2} in response to the test current I_{DUT2} generated by the activated transistor M2 within the second DUT group DG2.

FIG. 5A is a schematic diagram of the second measuring circuit 132 in the embodiment of FIG. 2. Please refer to FIGS. 2, 4, and 5A collectively.

In some embodiments, the second measuring circuit 132 is configured to receive the test current generated by a selected DUT, such as an N-type transistor, within the first DUT group DG1. The second measuring circuit 132 includes transistors MP1 and MP2, a transistor set MP3S, an operational amplifier 501, and switches SW11 to SW13. Transistors MP1 to MP2 may be P-type transistors. Transistor MP1 includes a gate terminal connected to an output terminal (e.g., node N1) of the operational amplifier 501, a source terminal coupled to a first input terminal (e.g., node N2) of the operational amplifier 501, and a drain terminal coupled to node N4. Transistor MP2 and the transistor set MP3S form a current mirror, which is capable of mirroring the test current I_{DUT1} generated by the activated DUT within the first DUT group DG1 (e.g., including DUTs 1101 to 110(N/2) in FIG. 2) by a predetermined ratio from 1/m to n/m, where n and m are positive integers. In some embodiments, transistor set MP3S may be a collective transistor device including n P-type transistors MP3 arranged in parallel, thereby providing n times driving strength of a single P-type transistor MP3, as depicted in FIG. 5A.

In some embodiments, transistor MP2 and transistor set MP3S can be implemented using any type of MOS devices, such as a cascode MOS device, a stacked gate device, a wide-swing device, etc., thereby enhancing the operation range of the current mirror and reducing the error or its mirrored current.

The operational amplifier 501 includes an output terminal (e.g. node N1) coupled to the gate terminal of transistor MP1, a first input terminal coupled to node N2, and a second input terminal coupled to node N3. Switch SW11 is coupled between nodes N4 and N5, where node N4 refers to the drain terminal of transistor MP1, and node N5 refers to the drain terminal of the activated DUT within the first DUT group DG1. Switch SW12 is coupled between node N3 and node N6, where node N3 may refer to the gate terminal of transistor MP2, the gate and drain terminals of transistor set MP3S, and node N6 may refer to an output terminal of the second measuring circuit 132 providing an output current I_{OUT1} to the test equipment 20. Switch SW13 is coupled between nodes N5 and N6. When activated, switch SW13 is configured to provide the test current I_{DUT1} to node N6 for direct measurement of the test current I_{DUT1} by the test equipment 20. In various embodiments, switches SW11 and SW12 are controlled by a first control signal (not shown), while switch SW13 is controlled by a second control signal (not shown) complementary to the first control signal. This indicates that when switches SW11 and SW12 are activated, switch SW13 is deactivated, and when switches SW11 and SW12 are deactivated, switch SW13 is activated. In some embodiments, the operational amplifier 501 may be implemented using a differential amplifier with a feedback loop.

In some embodiments, when switches SW11 and SW12 are activated and switch SW13 is deactivated, the current mirror within the second measuring circuit 132 operates normally, and the test current I_{DUT1} is changed by a mirror ratio (e.g., (1~n)/m) of the current mirror to generate the output current I_{OUT1}. It should be noted that because the operational amplifier 501 is used, the offset is non-sensitive which can be suppressed by the voltage gain of the operational amplifier 501. Furthermore, since the drain-to-source voltage of transistor MP2 and transistor set MP3S is locked by the operational amplifier 501, the error of the output current I_{OUT1} caused by device mismatch can be reduced. In some embodiments, when switches SW11 and SW12 are deactivated and switch SW13 is activated, the test current I_{DUT1} may flow from node N5 to node N6, and serves as the output current I_{OUT1} for direct measurement by the test equipment 20.

In some embodiments, the driving strength of the transistor set MP3S can be adjusted from 1 time to n times, depending on the number of active bits of an n-bit driving control signal (not shown) from the test equipment 20. In various non-limiting examples, the ratio of n/m may be 10. Accordingly, the mirror ratio of the driving strength of the transistor MP2 to that of transistor set MP3S may be from m:1 to m:n, where the number n is an adjustable positive integer (e.g., the number of active bits of the driving control signal). It should be noted that the driving strength of a transistor may refer to its width/length ratio for a planar device, a number of fins for a fin field-effect transistor (finFET), or a number of nanosheets or nanowires for a nanosheet FET.

In some embodiments, the test equipment 20 includes a load capacitance coupled to the output terminal (e.g., node N6) of the second measuring circuit 132. In various embodiments, the load capacitance may have a large capacitance value of greater than 100 pF. The test equipment 20 can calculate the overall charge time of the load capacitance with the output current I_{OUT1}, thereby estimating the test current I_{DUT1} of the activated DUT according to the driving control signal of transistor set MP3S. When the test current I_{DUT1} of the activated DUT within the first DUT group DG1 is a small current (e.g., hundreds of μA), with an appropriate design of the driving control signal of transistor set MP3S, the test current I_{DUT1} can be amplified n/m times by the current mirror formed by transistor MP2 and transistor set MP3S, thereby significantly reducing the testing time of the activated DUT. When the test current I_{DUT1} of the activated DUT within the first DUT group DG1 is a large current (e.g., in several mA), with an appropriate design of the driving control signal of transistor set MP3S, the test current I_{DUT1} can be divided by a ratio, mitigating the small IR drop issues for a large test current.

FIG. 5B is a schematic diagram of the first measuring circuit 131 in the embodiment of FIG. 2. Please refer to FIGS. 2, 4, and 5B collectively.

In some embodiments, the first measuring circuit 131 is configured to receive the test current generated by a selected DUT, such as a P-type transistor, within the second DUT group DG2. The first measuring circuit 131 includes transistors MN1 and MN2, a transistor set MN3S, an operational amplifier 502, and switches SW14 to SW16. Transistors MN1 to MN2 may be N-type transistors. Transistor MN1 includes a gate terminal connected to an output terminal (e.g., node N11) of the operational amplifier 502, a source terminal coupled to a first input terminal (e.g., node N12) of the operational amplifier 501, and a drain terminal coupled to node N14. Transistor MN2 and the transistor set MN3S form a current mirror, which is capable of mirroring the test current IDUT2 generated by the activated DUT within the second DUT group DG2 (e.g., including DUTs 110(N/2+1) to 110N in FIG. 2) by a predetermined ratio from 1/m to n/m, where n and m are positive integers. In some embodiments, transistor set MN3S may be a collective transistor device including n N-type transistors MN3 arranged in parallel, thereby providing n times driving strength of a single N-type transistor MN3, as depicted in FIG. 5B.

The operational amplifier 502 includes an output terminal (e.g. node N11) coupled to the gate terminal of transistor MN1, a first input terminal coupled to node N12, and a second input terminal coupled to node N13. Switch SW14 is coupled between nodes N14 and N15, where node N14 refers to the drain terminal of transistor MN1, and node N15 refers to the drain terminal of the activated DUT within the second DUT group DG2. Switch SW15 is coupled between node N13 and node N16, where node N13 may refer to the gate terminal of transistor MN2, the gate and drain terminals of transistor set MN3S, and node N16 may refer to an output terminal of the first measuring circuit 131 providing an output current I_{OUT2} to the test equipment 20. Switch SW16 is coupled between nodes N15 and N16. When activated, switch SW16 is configured to provide the test current I_{DUT2} to node N16 for direct measurement of the test current I_{DUT2} by the test equipment 20. In various embodiments, switches SW14 and SW15 are controlled by a third control signal (not shown), while switch SW16 is controlled by a fourth control signal (not shown) complementary to the third control signal. This indicates that when switches SW14 and SW15 are activated, switch SW16 is deactivated, and when switches SW14 and SW15 are deactivated, switch SW16 is activated.

In some embodiments, when switches SW14 and SW15 are activated and switch SW16 is deactivated, the current mirror within the first measuring circuit 131 operates normally, and the test current I_{DUT2} is changed by a mirror ratio (e.g., (1~n)/m) of the current mirror to generate the output current I_{OUT2}. It should be noted that because the operational amplifier 502 is used, the offset is non-sensitive which can be suppressed by the voltage gain of the operational amplifier 502. Furthermore, since the drain-to-source voltage of transistor MN2 and transistor set MN3S is locked by the operational amplifier 502, the error of the output current I_{OUT2} caused by device mismatch can be reduced. In some embodiments, when switches SW14 and SW15 are deactivated and switch SW16 is activated, the test current I_{DUT2} may flow from node N15 to node N16, and serves as the output current I_{OUT2} for direct measurement by the test equipment 20.

In some embodiments, the driving strength of the transistor set MN3S can be adjusted from 1 time to n times, depending on the number of active bits of an n-bit driving control signal (not shown) from the test equipment 20. In various non-limiting examples, the ratio of n/m may be 10. Accordingly, the mirror ratio of the driving strength of the transistor MN2 to that of transistor set MN3S may be from m:1 to m:n, where the number n is an adjustable positive integer (e.g., the number of active bits of the driving control signal). It should be noted that the driving strength of a transistor may refer to its width/length ratio for a planar device, a number of fins for a fin field-effect transistor (finFET), or a number of nanosheets or nanowires for a nanosheet FET.

In some embodiments, the test equipment 20 includes a load capacitance coupled to the output terminal (e.g., node N16) of the first measuring circuit 131. In various embodiments, the load capacitance may have a large capacitance value of greater than 100 pF. The test equipment 20 can calculate the overall charge time of the load capacitance with the output current I_{OUT2}, thereby estimating the test current I_{DUT2} of the activated DUT according to the driving control signal of transistor set MN3S. When the test current I_{DUT2} of the activated DUT within the second DUT group DG2 is a small current (e.g., in hundreds of μA), with an appropriate design of the driving control signal of transistor set MN3S, the test current I_{DUT2} can be amplified n/m times by the current mirror formed by transistor MN2 and transistor set MN3S, thereby significantly reducing the testing time of the activated DUT. When the test current I_{DUT2} of the activated DUT within the second DUT group DG2 is a large current (e.g., in several mA), with an appropriate design of the driving control signal of transistor set MN3S, the test current I_{DUT2} can be divided by a ratio, mitigating the small IR drop issues for a large test current.

It should be noted that the mirror ratio of the second measuring circuit 132 in FIG. 5A can be different from that of the first measuring circuit 131 in FIG. 5B. For example, the second measuring circuit 132 and the first measuring circuit 131 can have different driving control signals to control the number of activated transistors within the transistor sets MP3S and MN3S.

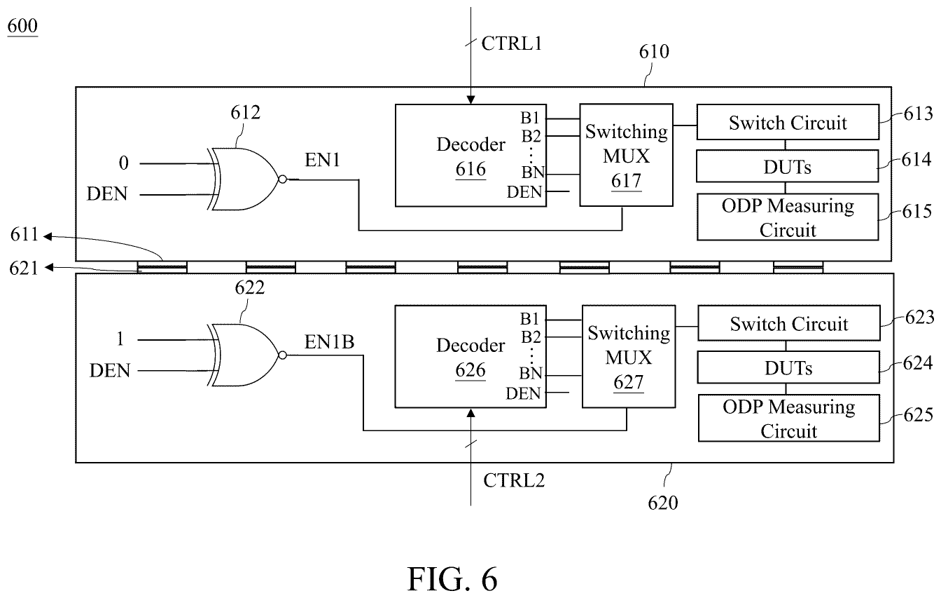

FIG. 6 is diagram illustrating a three-dimensional integrated circuit package including two dies in accordance with some embodiments of the present disclosure.

In some embodiments, the three-dimensional (3D) IC package 600 includes dies 610 and 620, which are a top die and a bottom die arranged in a stacked structure, with die 620 being flipped with an active side (or front side) on top. Dies 610 and 620 are electrically connected to each other via respective conductive elements 611 and 621, such as microbumps. In some embodiments, die 610 includes a switch circuit 613, DUTs 614, and an ODP measuring circuit 615, which are similar to those in FIGS. 1 and 2, the details of which will not be omitted here. In addition, die 610 further includes a decoder 616, a switching multiplexer (MUX) 617, and an XNOR gate 612. The decoder 616 is configured to receive a first control signal CTRL1 from the test equipment 20, and decode the first control signal CTRL1 to obtain a die enable signal DEN and corresponding bits B[1] to B[N] of the control signal B[1:N]. It should be noted that a first input terminal of the XNOR gate 612 is tied to 0, and the die enable signal DEN is sent to a second input terminal of the XNOR gate 612, thereby generating an enable signal EN1, which is sent to the switching MUX 617. The switching MUX 617 is configured to generate a corresponding control signal to select one of the DUTs 614 and activate its respective switch device and switches within the switch circuit 613 and the ODP measuring circuit 615. The ODP measuring circuit 615 is configured to generate an output current in response to the test current generated by the selected DUT, and send the output current to the test equipment 20 for measuring the test current.

In some embodiments, die 620 includes a switch circuit 623, DUTs 624, and an ODP measuring circuit 625, which are similar to those in FIGS. 1 and 2, the details of which will not be omitted here. In addition, die 620 further includes a decoder 626, a switching multiplexer (MUX) 627, and an XNOR gate 622. The decoder 626 is configured to receive a second control signal CTRL2 (or the first control signal CTRL1) from the test equipment 20, and decode the second control signal CTRL2 to obtain a die enable signal DEN and corresponding bits B[1] to B[N] of the control signal B[1:N]. It should be noted that a first input terminal of the XNOR gate 622 is tied to 1, and the die enable signal DEN is sent to a second input terminal of the XNOR gate 622, thereby generating an enable signal EN1B, which is sent to the switching MUX 627. The switching MUX 627 is configured to generate a corresponding control signal to select one of the DUTs 624 and activate its respective switch device and switches within the switch circuit 623 and the ODP measuring circuit 625. The ODP measuring circuit 625 is configured to generate an output current in response to the test current generated by the selected DUT, and send the output current to the test equipment 20 for measuring the test current.

It should be noted that during the ODP test of the 3D IC package 600, one of dies 610 and 620 is selected, and DUTs within the selected die are tested sequentially. The decoders 616 and 626 may generate the same die enable signal DEN that are respectively sent to the XNOR gates 612 and 622, ensuring one of dies 610 and 620 can be selected during the ODP test cycle for one die. For example, when the die enable signal DEN is in the low logic state (e.g., “0”), the enable signal EN1 is in the high logic state (e.g., “1”), and the enable signal EN1B is in the low logic state (e.g., “0”). Accordingly, the switching MUX 617 can perform an AND operation of each bit of the control signal B[1:N] with the enable signal EN1, allowing one bit of the control signal B[1:N] generated by decoder 616 to select one of the DUTs 614 and activate its respective switch device and switches, as described in the embodiment of FIG. 4. In contrast, when the die enable signal DEN is in the high logic state (e.g., “1”), the enable signal EN1 is in the low logic state (e.g., “0”), and the enable signal EN1B is in the high logic state (e.g., “1”). Accordingly, the switching MUX 627 can perform an AND operation of each bit of the control signal B[1:N] with the enable signal EN1B, allowing one bit of the control signal B[1:N] generated by decoder 626 to select one of the DUTs 624 and activate its respective switch device and switches, as described in the embodiment of FIG. 4.

This indicates that dies 610 and 620 can be controlled independently, and it does not need to implement dummy wires or circuits on the opposite die compared to some existing approaches, achieving independent testing for a single die and lowering the manufacturing costs.

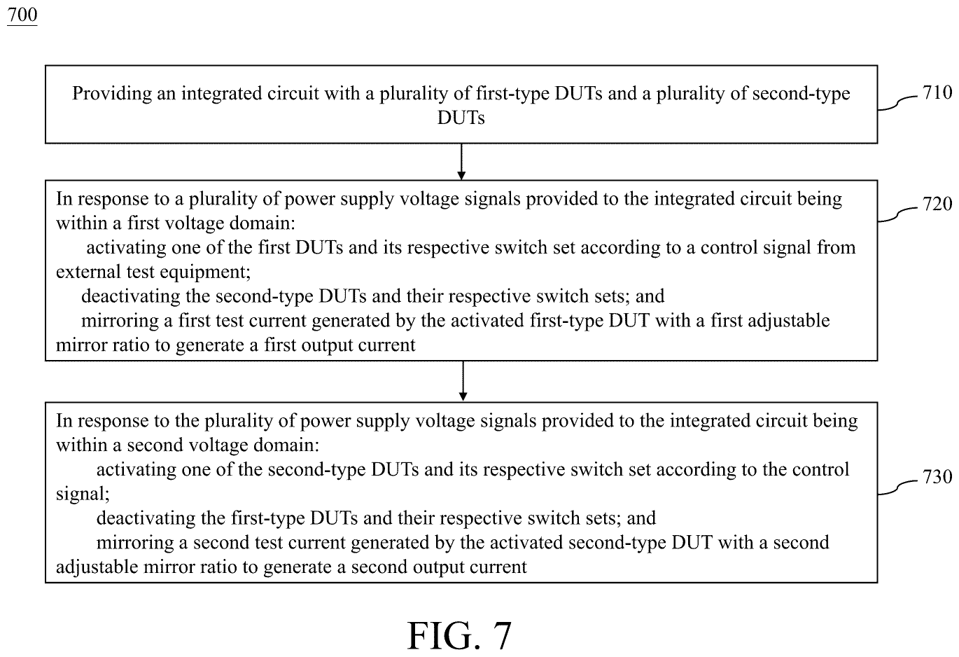

FIG. 7 is a flowchart of a method for operating an on-die parameter measuring circuit in accordance with some embodiments of the present disclosure. Please refer to FIGS. 1, 4, and 7 simultaneously. Flow 700 shown in FIG. 7 includes operations 710 to 730.

At operation 710, an integrated circuit with a plurality of first-type DUTs and a plurality of second-type DUTs is provided. In some embodiments, the first-type DUTs are N-type transistors, and the second-type DUTs are P-type transistors. In various embodiments, the first and DUTs can be devices of other types, such as BJTs, resistors, vias, metal wires, etc.

At operation 720, in response to a plurality of power supply voltage signals provided to the integrated circuit being within a first voltage domain, one of the first-type DUTs and its respective switch set are activated according to a control signal from external test equipment, a plurality of second-type DUTs and their respective switch sets are deactivated, a first test current generated by the activated first-type DUT is mirrored with a first adjustable mirror ratio to generate a first output current. In some embodiments, the first voltage domain is between the reference voltage V_{SS} and the middle power supply voltage V_{MID}. Accordingly, the voltage difference between any two terminals of the activated first-type DUT (e.g., a core device) can be within its voltage tolerance limit.

At operation 730, in response to the plurality of power supply voltage signals provided to the integrated circuit being within a second voltage domain, one of the second-type DUTs and its respective switch set are activated according to the control signal, the first-type DUTs and their respective switch sets are deactivated, and a second test current generated by the activated second-type DUT is mirrored with a second adjustable mirror ratio to generate a second output current. In some embodiments, the second voltage domain is between the middle power supply voltage V_{MID} and the high power supply voltage V_{HIGH}. Accordingly, the voltage difference between any two terminals of the activated second-type DUT (e.g., a core device) can be within its voltage tolerance limit. It should be noted that the order of operations 720 and 730 is exchangeable, depending on the voltage domain of the provided power supply voltage signals.

An aspect of the present disclosure provides an integrated circuit which includes a plurality of devices under test, a parameter measuring circuit, and a switch circuit. The switch circuit includes a plurality of respective switch sets of the plurality of devices under test. One of the plurality of devices under test is activated by its respective switch set in response to a control signal from external test equipment. The parameter measuring circuit is configured to generate an output current with an adjustable mirror ratio in response to a test current generated by the activated device under test, and send the output current to the external test equipment for measurement.

Another aspect of the present disclosure provides an integrated circuit which includes a plurality of first-type devices under test, a plurality of second-type devices under test, a parameter measuring circuit, and a switch circuit. The switch circuit includes a plurality of respective first switch sets of the first-type devices under test and a plurality of respective second switch sets of the second-type devices under test. One of the first-type devices under test and its respective first switch set, or one of the second-type devices under test and its respective second switch set, is activated according to a control signal from external test equipment and a voltage domain of a plurality of power supply voltage signals provided to the integrated circuit. The parameter measuring circuit is configured to generate an output current from a test current, which is generated by the activated first-type DUT or second-type DUT, using an adjustable mirror ratio, and send the output current to the external test equipment for measurement.

Yet another aspect of the present disclosure provides a method. An integrated circuit with a plurality of first-type devices under test (DUTs) and a plurality of second-type DUTs is provided. In response to a plurality of power supply voltage signals provided to the integrated circuit being within a first voltage domain, one of the first-type DUTs and its respective switch set are activated according to a control signal from external test equipment, the second-type DUTs and their respective switch sets are deactivated, a first test current generated by the activated first-type DUT is mirrored with a first adjustable mirror ratio to generate a first output current.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. An integrated circuit, comprising:
a plurality of devices under test (DUTs);
a parameter measuring circuit; and
a switch circuit, comprising a plurality of respective switch sets of the plurality of DUTs,
wherein one of the plurality of DUTs is activated by its respective switch set in response to a control signal from external test equipment,
wherein the parameter measuring circuit is configured to generate an output current with an adjustable mirror ratio in response to a test current generated by the activated DUT, and send the output current to the external test equipment for measurement.

2. The integrated circuit of claim 1, wherein the DUTs are categorized into a first half comprising a plurality of first transistors of a first type, and a second half comprising a plurality of second transistors of a second type.

3. The integrated circuit of claim 2, wherein the first transistors operate in a first voltage domain, and the second transistors operate in a second voltage domain different from the first voltage domain.

4. The integrated circuit of claim 3, wherein the second voltage domain is higher than the first voltage domain.

5. The integrated circuit of claim 4, wherein the first transistors are N-type transistors, and the second transistors are P-type transistors.

6. The integrated circuit of claim 4, wherein:
the first voltage domain is between a reference voltage and a middle power supply voltage;
the second voltage domain is between the middle power supply voltage and a high power supply voltage;
the high power supply voltage is higher than the middle power supply voltage; and
the middle power supply voltage is higher than the reference voltage.

7. The integrated circuit of claim 4, wherein:
in response to a first voltage signal, a second voltage signal, and a third voltage signal provided to the integrated circuit being in the first voltage domain, the respective switch sets corresponding to the second transistors are deactivated; and
in response to the first voltage signal, the second voltage signal, and the third voltage signal provided to the integrated circuit being in the second voltage domain, the respective switch sets corresponding to the first transistors are deactivated.

8. The integrated circuit of claim 6, wherein a voltage difference between any two terminals of each first transistor is less than to a differential voltage by subtracting the reference voltage from the middle power supply voltage.

9. The integrated circuit of claim 6, wherein a voltage difference between any two terminals of each second transistor is less than a differential voltage by subtracting the middle power supply voltage from the high power supply voltage.

10. The integrated circuit of claim 2, wherein the parameter measuring circuit comprises:
a first measuring circuit, configured to generate the output current with the adjustable mirror ratio in response to the test current generated by the activated DUT, which is one of the first transistors; and
a second measuring circuit, configured to generate the output current with the adjustable mirror ratio in response to the test current generated by the activated DUT, which is one of the second transistors.

11. The integrated circuit of claim 10, wherein the first measuring circuit comprises:
a first current mirror, comprising:
a third transistor of the second type; and
a first transistor set, comprising a plurality of fourth transistors of the second type;
a first operational amplifier, coupled to the first current mirror, and configured to lock a voltage difference across two terminals of the third transistor and the fourth transistors; and
a fifth transistor, having a gate terminal coupled to an output terminal of the first operational amplifier, a first terminal coupled to the third transistor, and a second terminal coupled to the activated DUT of the first type.

12. The integrated circuit of claim 11, wherein the second measuring circuit comprises:
a second current mirror, comprising:
a sixth transistor of the first type; and
a second transistor set, comprising a plurality of seventh transistors of the second type;
a second operational amplifier, coupled to the second current mirror, and configured to lock a voltage difference across two terminals of the sixth transistor and the seventh transistors; and
a eighth transistor, having a gate terminal coupled to an output terminal of the second operational amplifier, a first terminal coupled to the sixth transistor, and a second terminal coupled to the activated DUT of the second type.

13. An integrated circuit, comprising:
a plurality of first-type devices under test (DUTs);
a plurality of second-type DUTs;
a parameter measuring circuit; and
a switch circuit, comprising a plurality of respective first switch sets of the first-type DUTs, and a plurality of respective second switch sets of the second-type DUTs,
wherein one of the first-type DUTs and its respective first switch set, or one of the second-type DUTs and its respective second switch set are activated according to a control signal from external test equipment and a voltage domain of a plurality of power supply voltage signals provided to the integrated circuit,
wherein the parameter measuring circuit is configured to generate an output current from a test current, which is generated by the activated first-type DUT or second-type DUT, using an adjustable mirror ratio, and send the output current to the external test equipment for measurement.

14. The integrated circuit of claim 13, wherein:
the plurality of power supply voltage signals comprise a first voltage signal, a second voltage signal, and a third voltage signal;
when the voltage domain of the first voltage signal, the second voltage signal, and the third voltage signal is within a first voltage domain, the respective second switch sets of the second-type DUTs are deactivated;
when the voltage domain of the first voltage signal, the second voltage signal, and the third voltage signal is within a second voltage domain, the respective first switch sets of the first-type DUTs are deactivated; and
the second voltage domain is higher than the first voltage domain.

15. The integrated circuit of claim 14, wherein:
the first voltage domain is between a reference voltage and a middle power supply voltage;
the second voltage domain is between the middle power supply voltage and a high power supply voltage;
the high power supply voltage is higher than the middle power supply voltage; and
the middle power supply voltage is higher than the reference voltage.

16. The integrated circuit of claim 14, wherein the parameter measuring circuit comprises:
a first measuring circuit, configured to generate the output current with a first adjustable mirror ratio in response to the test current generated by the activated first-type DUT; and
a second measuring circuit, configured to generate the output current with a second adjustable mirror ratio in response to the test current generated by the activated second-type DUT.

17. The integrated circuit of claim 16, wherein the first-type DUTs are N-type transistors, and the second-type DUTs are P-type transistor.

18. A method, comprising:
providing an integrated circuit with a plurality of first-type devices under test (DUTs) and a plurality of second-type DUTs; and
in response to a plurality of power supply voltage signals provided to the integrated circuit being within a first voltage domain:
activating one of the first DUTs and its respective switch set according to a control signal from external test equipment;
deactivating the second-type DUTs and their respective switch sets; and
mirroring a first test current generated by the activated first-type DUT with a first adjustable mirror ratio to generate a first output current.

19. The method of claim 18, further comprising:
in response to the plurality of power supply voltage signals provided to the integrated circuit being within a second voltage domain:
activating one of the second-type DUTs and its respective switch set according to the control signal;
deactivating the first-type DUTs and their respective switch sets; and
mirroring a second test current generated by the activated second-type DUT with a second adjustable mirror ratio to generate a second output current,
wherein the second voltage domain is higher than the first voltage domain.

20. The method of claim 19, further comprising:
utilizing the external test equipment to measure the first test current using the first output current; and
utilizing the external test equipment to measure the second test current using the second output current.
